(19) United States
(12) Patent Application Publication
(10) Pub. No.: US 2025/0343160 A1
(43) Pub. Date: Nov. 6, 2025

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: In Rak KIM, Incheon (KR); Na Ri KIM, Incheon (KR); Ga Young SHIN, Gyeonggi-do (KR); Young Do KWEON, Chandler, AZ (US); Min Cheol SHIN, Gyeonggi-do (KR); Jae Min BAE, Seoul (KR); Chang Hun KIM, Incheon (KR)

(73) Assignee: Amkor Technology Singapore Holding Pte. Ltd., Valley Point #12-03 (SG)

(21) Appl. No.: 18/654,376

(22) Filed: May 3, 2024

(51) Int. Cl. H01L 23/00; H01L 21/56; H01L 23/31; H01L 23/48; H01L 25/00; H01L 25/065

(52) U.S. Cl. CPC H01L 23/562; H01L 21/568; H01L 23/3128; H01L 23/3185; H01L 24/29; H01L 24/32; H01L 23/481; H01L 24/08; H01L 24/13; H01L 24/16; H01L 24/73; H01L 25/0652; H01L 25/50; H01L 2224/08225; H01L 2224/13111; H01L 2224/13116; H01L 2224/13147; H01L 2224/16225; H01L 2224/2929; H01L 2224/29291; H01L 2224/29324; H01L 2224/29339; H01L 2224/29386; H01L 2224/29393; H01L 2224/32225; H01L 2224/32245; H01L 2224/73204; H01L 2924/01006; H01L 2924/0132; H01L 2924/0503; H01L 2924/0543; H01L 2924/0665; H01L 2924/069; H01L 2924/0715

(57) ABSTRACT

In one example, an electronic device includes a substrate including a first side with a peripheral portion and a central portion, a second side, a lateral side, a dielectric structure, and a conductive structure. An electronic component includes a component first side coupled to the conductive structure in the central portion, a component second side, and a component lateral side. A stiffener is coupled to the first side in the peripheral portion and includes an inner wall, an outer wall opposite to the inner wall, and a top side. An encapsulant covers the inner wall, the outer wall, and the component lateral side, and a portion of the first side. The component second side can be exposed from the top side of the encapsulant. Other examples and related methods are also disclosed herein.

### CROSS-REFERENCE TO RELATED APPLICATIONS

Not applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, 2E, 2F, 2G, 2G-1, 2H, 2I, and 2I-1 show cross-sectional views of an example method for manufacturing an example electronic device.

FIG. 3 shows a cross-sectional view of an example electronic device.

FIGS. 4A, 4B, 4C, 4D, 4E, 4F, and 4F-1 show cross-sectional views of an example method for manufacturing an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical coupling or a mechanical coupling.

### DESCRIPTION

The present description includes, among other features, structures and associated methods that relate to packaged electronic devices that are more resilient to thermal stress. More particularly, structures and methods are described that improve the reliability of packaged electronic devices that reduce defects associated with thermal stress, such as warpage, package distortion, bending, component cracking, or delamination. In some examples, a first stiffener is provided at a peripheral edge of a substrate with one or more electronic components placed on the substrate inside the perimeter of the stiffener. An encapsulant encapsulates the stiffener and the electronic components. In some examples, lateral sides and the top side of the stiffener are covered by or embedded within the encapsulant. In some examples, the lateral sides are covered by the encapsulant and the top side of the stiffener is exposed from the encapsulant. In some examples, the stiffener comprises a material that can be selectively removed using, for example, a grinding process. This conveniently sets the thickness of the stiffener after the stiffener is encapsulated. In some examples, component sides of the electronic components can be exposed from the top side of the encapsulant. In some examples, a lid can be coupled to or overlie the stiffener. In some examples, the lid comprises an opening and the components sides are exposed within the opening. In some examples, the lid can be configured as an additional stiffener. The stiffener(s) reduces the occurrence of warpage, package distortion, bending, component cracking, or delamination thereby improving the reliability of the electronic package. In addition, because the lateral sides (including the outer walls) of the stiffener are covered by or embedded within the encapsulant, the attachment integrity between the encapsulant, the substrate, and the stiffener is improved.

In some examples, the stiffener(s) of the present description can be used in a molded exposed die Flip Chip Ball Grid Array (FCBGA) configuration. In such a configuration, first electronic components can be arrayed on a thin core or coreless substrate around the periphery of electronic components and the stiffener is placed at the periphery of the thin core or coreless substrate around the electronic components. In some examples, one or more of the electronic components can have a larger footprint compared to the footprints of other electronic components. It was found through experimentation that the combination of thin core or coreless substrates with larger footprint electronic components are susceptible to package warpage and that the addition of a stiffener(s) as described hereinafter reduces such packaged warpage and reduces the occurrence of undesirable curvature in the electronic package. In accordance with the present description, the stiffener(s) is provided to counteract and mitigate the tendency towards package warpage. In some examples, the dimensions of the stiffener(s) are selected to further improve the support and stability so that the electronic package better maintains the desired flatness and complies with required package warpage specifications. This improves the reliability and performance of packaged electronic devices.

In an example, an electronic device includes a substrate including a substrate first side comprising a peripheral portion and a central portion surrounded by the peripheral portion, a substrate second side opposite to the substrate first side, a substrate lateral side, a dielectric structure, and a conductive structure. A first electronic component includes a component first side coupled to the conductive structure at the substrate first side of the substrate in the central portion, a component second side opposite to the component first side, and a component lateral side connecting the component first side to the component second side. A stiffener is coupled to the substrate first side in the peripheral portion and including, an inner wall, an outer wall opposite to the inner wall, and a top side. An encapsulant covers the inner wall, the outer wall, and the component lateral side, and a portion of the substrate first side. In an example, the component second side is exposed from a top side of the encapsulant.

In an example, an electronic device includes a substrate including a substrate first side comprising a peripheral portion and a central portion surrounded by the peripheral portion, a substrate second side opposite to the substrate first side, a substrate lateral side, a dielectric structure, and a conductive structure. A first electronic component includes a component first side coupled to the conductive structure at the substrate first side of the substrate in the central portion, a component second side opposite to the component first side, and a component lateral side connecting the component first side to the component second side. A stiffener is coupled to the substrate first side in the peripheral portion and includes an inner wall, an outer wall opposite to the inner wall and laterally inset from the substrate lateral side, and a top side. An encapsulant covers the inner wall, the outer wall, and the component lateral side, and a portion of the substrate first side. A lid is coupled to the top side of the encapsulant.

In an example, a method of manufacturing an electronic device includes providing a substrate including a substrate first side comprising a peripheral portion and a central portion surrounded by the peripheral portion, a substrate second side opposite to the substrate first side, a substrate lateral side, a dielectric structure, and a conductive structure. The method includes providing a first electronic component including a component first side coupled to the conductive structure at the substrate first side of the substrate in the central portion, a component second side opposite to the component first side, and a component lateral side connecting the component first side to the component second side. The method includes providing a stiffener coupled to the substrate first side in the peripheral portion and including an inner wall, an outer wall opposite to the inner wall, and a top side. The method includes providing an encapsulant covering the inner wall, the outer wall, and the component lateral side, and a portion of the substrate first side, wherein the component second side is exposed from a top side of the encapsulant.

Other examples are included in the present disclosure. Such examples may be found in the figures, in the claims, or in the description of the present disclosure.

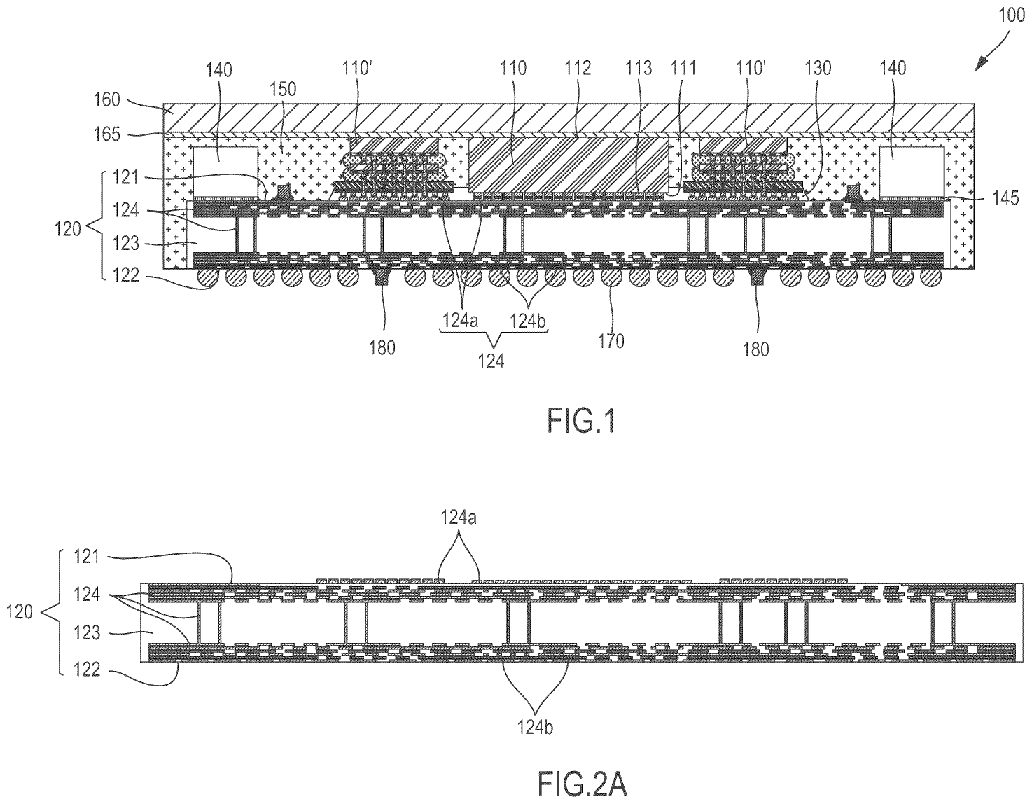

FIG. 1 shows a cross-sectional view of an example electronic device 100. In the example shown in FIG. 1, electronic device 100 can comprise one or more electronic components 110, one or more electronic components 110′, substrate 120, stiffener 140, encapsulant 150, lid 160, and external interconnects 170. In some examples, electronic device 100 can comprise underfill material 130. In some examples, electronic device 100 can comprise one or more electronic components 180 adjacent to external interconnects 170. Stiffener 140 is an example of a thermal stress reducing structure.

In some examples, electronic component 110 can comprise component first side 111, component second side 112 opposite to component first side 111, and connectors 113 proximate to component first side 111. A component lateral side connects component first side 111 to component second side 112. In some examples, component first side 111 can comprise or be referred to as an active side where circuit elements, device structures, and interconnect structures can be formed, and component second side 112 can comprise or be referred to as an inactive side. In some examples, component first side 111 can comprise or be referred to as a component bottom side and component second side 112 can comprise or be referred to as a component top side. In some examples, connectors 113 can comprise or be referred to as contact pads, bumps, tin/lead (SnPb) bumps, leadfree bumps, CuP, stud bumps, pillars, posts, solder capped pillars, or solder coated copper core balls., which can be coupled to circuit elements, device structures, or interconnect structures formed as part of electronic component 110. Although only one electronic component 110 is shown in FIG. 1, it is understood that electronic device 100 can comprise a plurality of electronic components 110 comprising component first sides 111, component second sides 112, and connectors 113.

Substrate 120 can comprise substrate first side 121, substrate second side 122 opposite to substrate first side 121, dielectric structure 123, and conductive structure 124. Conductive structure 124 can comprise substrate inward terminals 124a and substrate outward terminals 124b, which can be coupled to substrate inward terminals 124a. In some examples, connectors 113 can be coupled to substrate inward terminals 124a. In some examples, stiffener 140 can be coupled to substrate first side 121 with stiffener adhesive 145 at a peripheral portion of substrate 120, and lid 160 can be coupled to encapsulant 150 with lid adhesive 165. Substrate first side 121 can comprise or be referred to as a substrate top side and substrate second side 122 can comprise or be referred to as a substrate bottom side. Stiffener 140 can be an example of a first stiffener, an embedded stiffener, or a pre-molding stiffener.

In the present example, electronic component 110 is coupled to substrate 120 in a flip-chip configuration or active side down configuration with component first side 111 facing substrate first side 121. Underfill material 130 can be interposed between electronic component 110 and substrate 120 and can laterally surround connectors 113. In some examples, underfill material 130 can be along the lateral side of electronic component 110. Underfill material 130 can be configured to protect connectors 113 and to improve the adhesion of electronic component 110 to substrate 120. Underfill material 130 can comprise or be referred to as an interface material. In other examples, component second side 112 of electronic component 110 can be attached to substrate first side 121 and electronic component 110 be coupled to substrate inward terminals 124a with conductive interconnect structures, such as wire bonds.

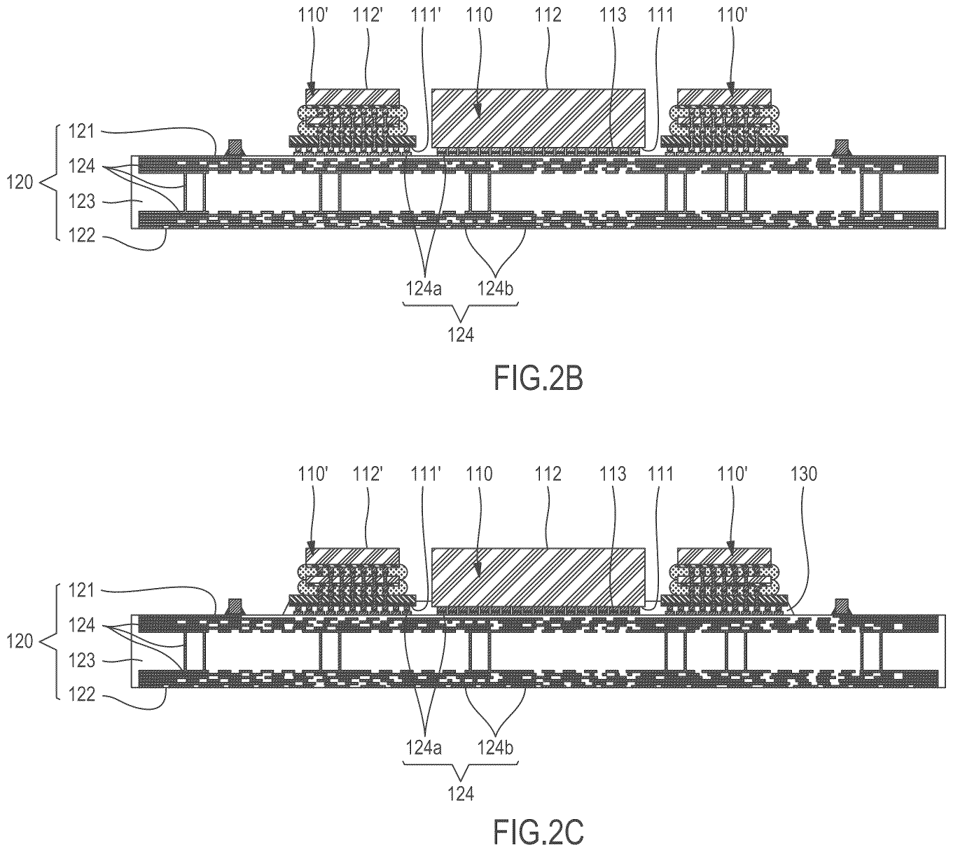

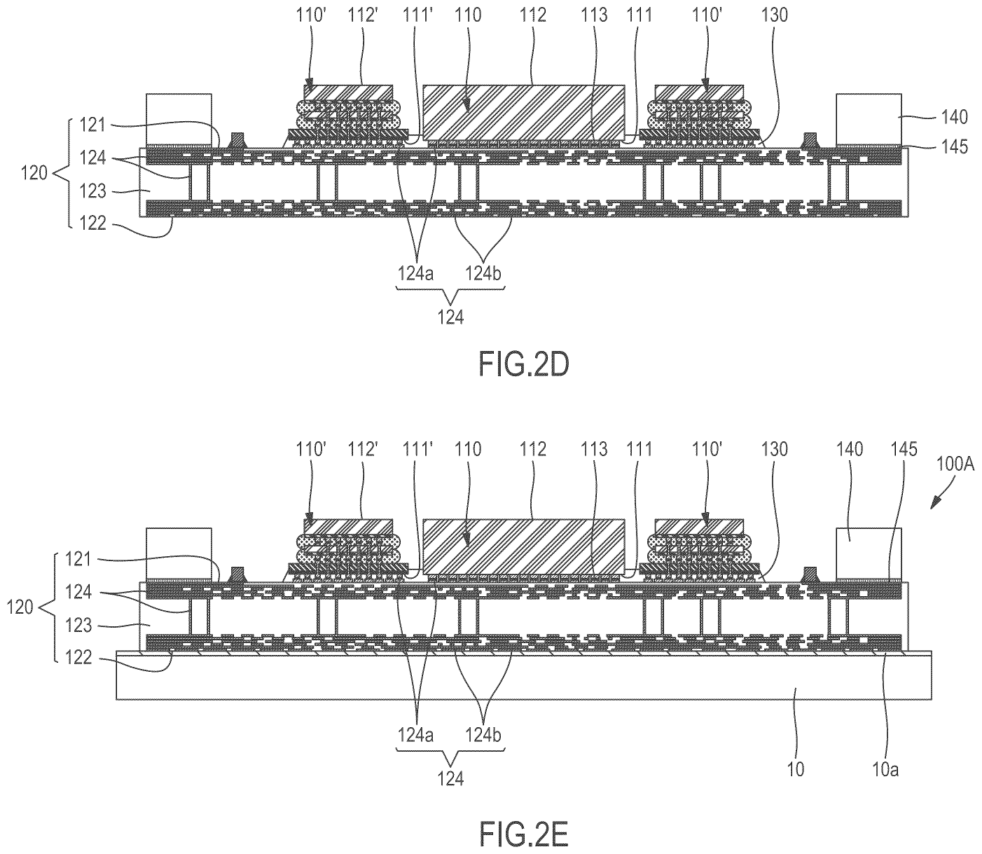

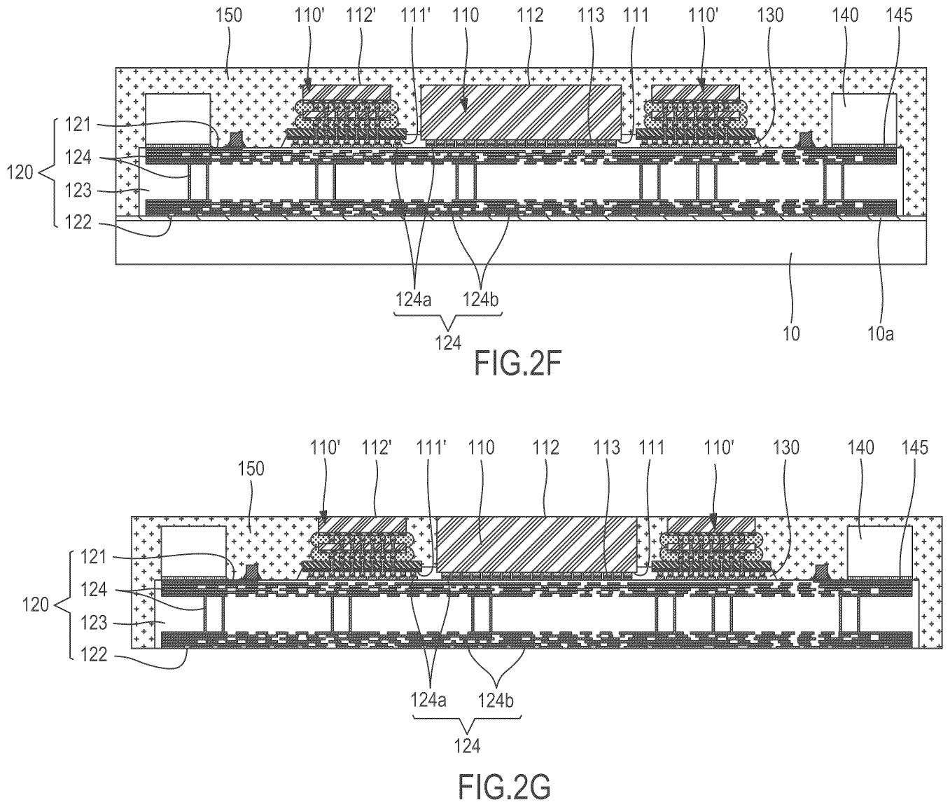

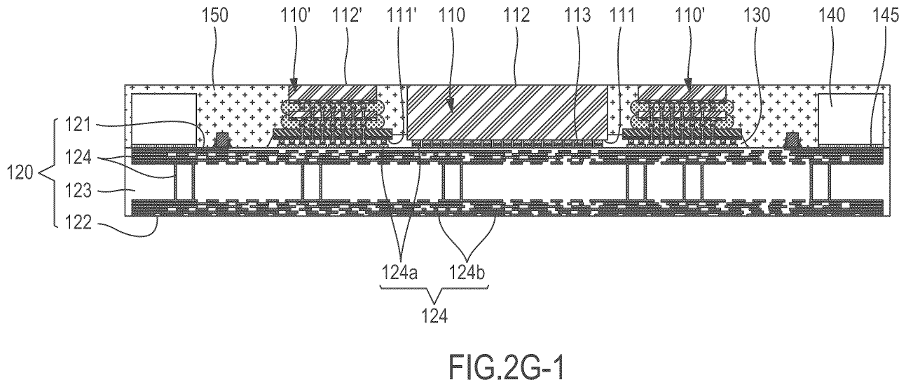

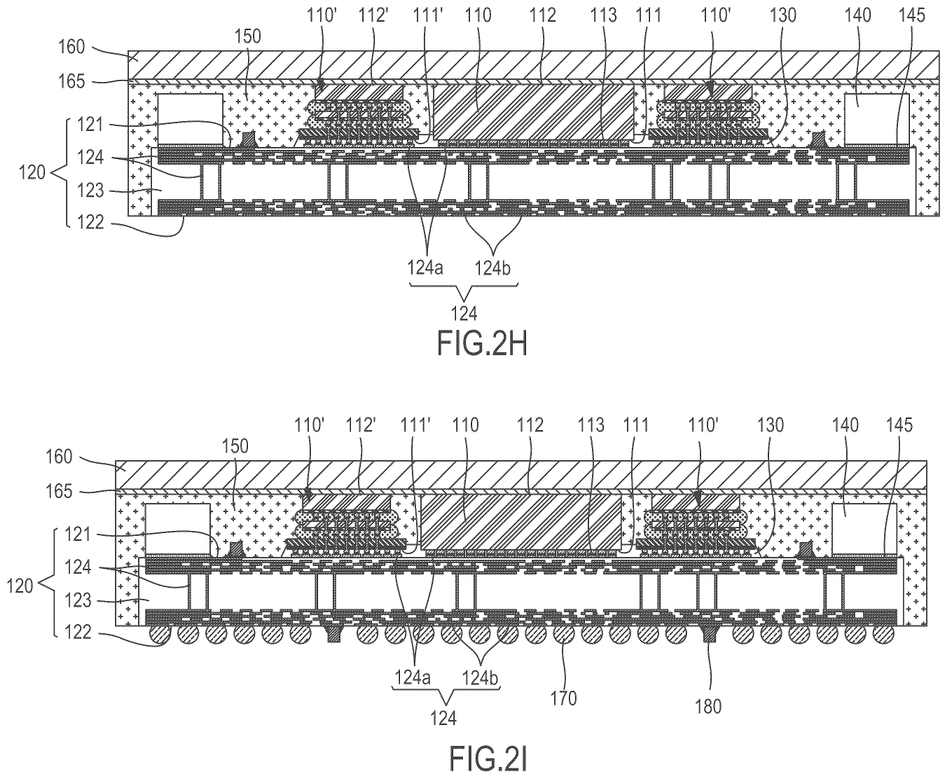

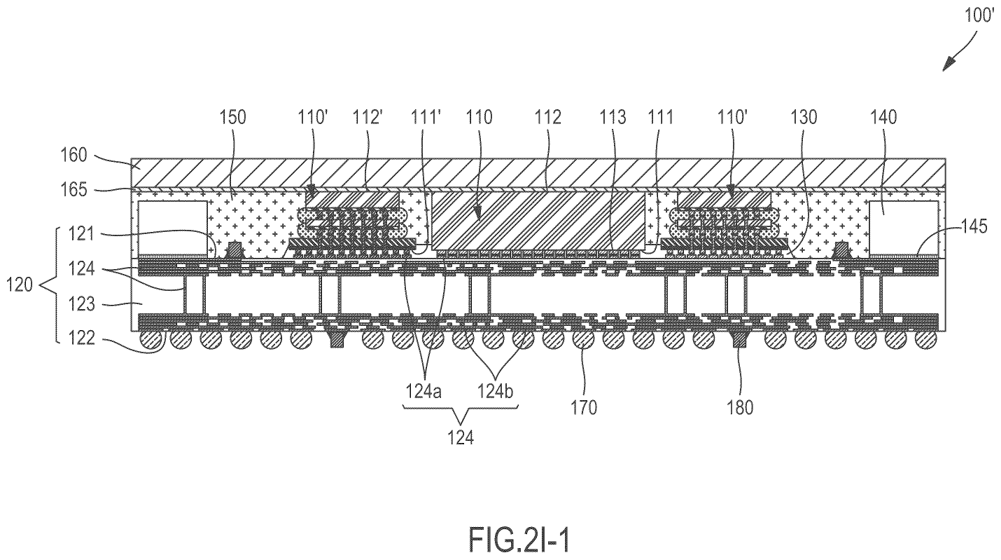

In the present example, encapsulant 150 is over substrate first side 121 and laterally surrounds and covers an inner wall, an outer wall opposite to the inner wall, and the top side of stiffener 140, laterally surrounds electronic component 110, and laterally surrounds electronic components 110′. In some examples, component second side 112 of electronic component 110 and component second sides 112′ (see e.g., FIG. 2B) of electronic components 110′ can be substantially coplanar and exposed from a top side of encapsulant 150. In some examples, lid 160 is coupled to the top side of encapsulant 150. In some examples, lid 160 is attached to the top side of encapsulant 150 with lid adhesive 165 and laterally extends to overlie electronic components 110 and 110′. Stiffener 140 is configured to reduce warpage of electronic device 100. Stiffener 140 is an example of a thermal stress reducing structure that is embedded within encapsulant 150. In some examples, encapsulant 150 can extend vertically to overlap the lateral side of substrate 120, which extends between substrate first side 121 and substrate second side 122. The lateral side of substrate 120 can comprise or be referred to as substrate lateral sides.

Substrate 120, underfill material 130, stiffener 140, encapsulant 150, lid 160, and external interconnects 170 can be referred to as an electronic package or a package. The electronic package can provide protection for electronic components 110 and 110′ from external elements or environmental exposure. The electronic package can also provide electrical coupling between electronic components 110, between electronic component 110 and electronic components 110′, or between electronic components 110 or 110′ and an external component or other electronic packages.

FIGS. 2A, 2B, 2C, 2D, 2E, 2F, 2G, 2G-1, 2H, 2I and 2I-1 show cross-sectional views of an example method for manufacturing an electronic device, such as electronic device 100.

FIG. 2A shows a cross-sectional view of electronic device 100 at an early stage of manufacture. In the example shown in FIG. 2A, substrate 120 can be provided. In some examples, the thickness of substrate 120 can vary, with a maximum thickness of approximately 3.5 millimeters (mm) and a core thickness in a range from approximately 1.2 mm to approximately 1.4 mm. In some examples, substrate 120 can comprise a thin core. As used herein, a “thin core” means a substrate core having a thickness of less than 1.24 mm. For example, substrate 120 can comprise a core thickness in a range of approximately 0.5 mm to approximately 1.20 mm, approximately 0.5 mm to approximately 1.00 mm, or of approximately 0.8 mm. In some examples, substrate 120 can have a total thickness of between 1.5 mm and 2.5 mm and a core thickness of between 0.5 mm and 1.0 mm. In some examples, substrate 120 can have a total thickness of between 2.0 mm and 2.2 mm and a core thickness of about 0.8 mm. In some examples, substrate 120 can be coreless. For example, the thickness of substrate 120 can be in a range of approximately 40 μm (microns) to approximately 3500 μm, approximately 100 μm to approximately 1500 μm, or approximately 800 μm to approximately 1000 μm. In some examples, substrate 120 can comprise or be referred to as a laminate substrate, a redistribution layer (RDL) substrate, a buildup substrate, a coreless substrate, a rigid substrate, a glass substrate, a semiconductor substrate, a printed circuit board, a multi-layer substrate, a molded lead frame, a ceramic substrate, a glass substrate, a silicon substrate, or a package substrate. Substrate 120 can couple electronic components to each other or to external devices and can protect the electronic components from external stress.

As described previously, substrate 120 comprises substrate first side 121, substrate second side 122, substrate lateral side connecting substrate first side 121 to substrate second side 122, dielectric structure 123, and conductive structure 124. Substrate first side 121 can be configured to receive electronic components 110 and 110′ (FIG. 1). Substrate second side 122 can be configured to receive external interconnects 170 and, in some examples, electronic components 180 (FIG. 1).

In some examples, dielectric structure 123 can comprise or be referred to as one or more dielectrics, dielectric materials, dielectric layers, passivation layers, insulating layers, or protective layers. In some examples, dielectric structure 123 can have a structure where one or more dielectric layers are stacked or interleaved with layers of conductive structure 124. In some examples, dielectric structure 123 can comprise FR4 (copper foil/glass fiber fabric/copper foil laminate), bismaleimide triazine (BT), polyimide (PI), benzocyclobutene (BCB), polybenzoxazole (PBO), Ajinomoto Build-up Film (ABF), resin, mold compound, ceramic, glass, or silicon. The thickness of individual layers of dielectric structure 123 can range from approximately 1 μm to approximately 1400 μm. The combined thickness of all layers of dielectric structure 123 can define the thickness of substrate 120. The individual layers of dielectric structure 123 can have different thicknesses and can comprise different materials.

Dielectric structure 123 can maintain the outer shape of substrate 120 and can also structurally support conductive structure 124, electronic component 110, and electronic component 110′. In some examples, dielectric structure 123 can be in contact with conductive structure 124. Dielectric structure 123 can expose portions of conductive structure 124. For example, substrate inward terminals 124a can be exposed from an upper side of dielectric structure 123 and substrate outward terminals 124b can be exposed from a lower side of dielectric structure 123. In some examples, dielectric structure 123 can be provided by spin coating, spray coating, printing, oxidation, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), or other processes as known to one of ordinary skill in the art.

Conductive structure 124 can comprise or be referred to as one or more conductive layers defining signal distribution elements, traces, vias, pads, patterns, conductive paths or under bump metals (UBMs). In some examples, conductive structure 124 can comprise copper (Cu), aluminum (Al), nickel (Ni), palladium (Pd), titanium (Ti), tungsten (W), titanium/tungsten, gold (Au), silver (Ag), an alloy, or other suitably conductive material as known to one of ordinary skill in the art. In some examples, conductive structure 124 can be provided by sputtering, electroless plating, electrolytic plating, PVD, CVD, MOCVD, ALD, LPCVD, PECVD, or other processes as known to one of ordinary skill in the art. The thickness of conductive structure 124 can range from approximately 1 μm to approximately 50 μm. The thickness of conductive structure 124 can refer to individual layers of conductive structure 124. Conductive structure 124 can provide an electrical signal path (e.g., a vertical path or a horizontal path) through substrate 120.

In some examples, conductive structure 124 can comprise substrate inward terminals 124a, which can also be referred to as or comprise inner contact pads, traces, or lands, and substrate outward terminals 124b, which can also be referred to as or comprise outer contact pads, traces, or lands. In some examples, substrate inward terminals 124a can be provided on or proximate to the top side of dielectric structure 123 (e.g., on or proximate to substrate first side 121). In some examples, substrate inward terminals 124a can be exposed from the top side of dielectric structure 123 (e.g., exposed from substrate first side 121). Substrate inward terminals 124a can be coupled to other elements of conductive structure 124. In some examples, substrate inward terminals 124a can comprise Cu, Al, Au, Ag, Ni, Pd, or an alloy. The thicknesses of substrate inward terminals 124a can range from approximately 1 μm to approximately 50 μm.

In some examples, substrate outward terminals 124b can be provided on or proximate to the bottom side of dielectric structure 123 (e.g., provided on or proximate to substrate second side 122). In some examples, substrate outward terminals 124b can be exposed from the bottom side of dielectric structure 123. Substrate outward terminals 124b can be coupled to other elements of conductive structure 124. In some examples, substrate outward terminals 124b can comprise Cu, Al, Au, Ag, Ni, Pd, or an alloy. The thicknesses of substrate outward terminals 124b can range from approximately 1 μm to approximately 50 μm. External interconnects 170, passive or active component 180 or other components or packages can be coupled to substrate outward terminals 124b in subsequent processing. In some examples, substrate inward terminals 124a or substrate outward terminals 124b can be provided in a matrix form having rows or columns. Conductive structure 124 can transmit signals, currents, or voltages within substrate 120. Conductive structure 124 can provide an electrical signal path (e.g., a vertical path or a horizontal path) between electronic components.

Substrate 120 can be manufactured using various processing techniques. For example, when substrate 120 comprises a two-layer FR4 substrate, substrate 120 can be manufactured by the steps of: processing a drill hole to couple a top copper foil and a bottom copper foil; coupling the top copper foil and the bottom copper foil by performing electroplating on the drill hole; providing a photosensitive film on the side of the substrate and photo-etching the photosensitive film so the sides of the top copper foil and the bottom copper foil are patterned, thereby patterning an outer layer circuit including substrate inward terminals 124a and substrate outward terminals 124b on substrate first side 121 and substrate second side 122; providing a seed layer for plating, and is thinner than the outer circuit by performing electroless plating on the entire top side and bottom side of the substrate to cover the outer circuit; providing a photosensitive film on the seed layer for plating so as to cover the seed layer for plating, and performing photo-etching on the photosensitive film to pattern the seed layer for plating; providing a solder resist layer on the entire top side and bottom side of the substrate so the outer circuit is exposed; and forming a plating layer on the outer circuit including substrate inward terminals 124a and substrate outward terminals 124b exposed out of the solder resist layer by applying electricity to the plating seed layer.

In an example where substrate 120 comprises a three to six-layer substrate having more than two layers, an inner-layer circuit providing step and a laminating step can be performed on substrate 120. As an example, the inner-layer circuit providing step can be performed by patterning an inner layer circuit on the top side and bottom side of each substrate by photo-etching a photosensitive film, so the sides of a top copper foil and a bottom copper foil are patterned for each substrate. As an example, the lamination step can be performed by aligning each of the provided substrates and allowing each of the substrates to be integrated into one substrate while providing a predetermined temperature and pressure. In some examples, the dielectric structure can be a B-stage prepreg, and since the dielectric structure is in a C-stage state after the lamination step, each substrate can be integrated to provide one multilayer substrate. In some examples, after the lamination process, a hole processing step, a plating step, or an outer layer circuit providing step can be sequentially provided in similar manner as described above.

In some examples, substrate 120 can be a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate omitting the permanent core structure, and the dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process.

In other examples, substrate 120 can be an RDL substrate. RDL substrates can comprise one or more conductive redistribution layers and one or more dielectric layers that (a) can be formed layer by layer over an electronic device to which the RDL substrate is to be coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si₃N₄), silicon oxide (SiO₂), and/or silicon oxynitride (SiON). The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate.

FIG. 2B shows a cross-sectional view of electronic device 100 at a later stage of manufacture. In the example shown in FIG. 2B, one or more electronic components, such as electronic components 110 and 110′ can be coupled to substrate first side 121. In the present example, multiple electronic components 110 will be described, but it is understood a single electronic component can be used.

Electronic components 110 or 110′ or other components or packaged devices can be coupled to substrate inward terminals 124a in a subsequent process. In some examples, electronic components 110′ can be initially coupled to substrate inward terminals 124a. In some examples, electronic components 110′ can be coupled to substrate 120 during a subsequent coupling process of electronic components 110, or electronic components 110′ can be coupled after the coupling process of electronic components 110. In some examples, multiple electronic components can be arrayed around substrate first side 121. In some examples, the area of substrate first side 121 is pre-determined to accommodate electronic components, such as electronic components 110 and 110′ in a central portion of substrate first side 121 and to accommodate stiffener 140 at the peripheral portion of substrate first side 121.

In some examples, electronic component 110 comprises component first side 111, component second side 112 opposite to component first side 111, and a component lateral side connecting component first side 111 to component second side 112. In some examples, component first side 111 can be oriented toward substrate first side 121. Electronic component 110 can also comprise connectors 113 proximate to component first side 111. Connectors 113 can couple electronic component 110 to conductive structure 124 of substrate 120, and can comprise or be referred to as pads, bumps, tin/lead (SnPb) bumps, leadfree bumps, CuP, stud bumps, pillars, posts, solder capped pillars, or solder coated copper core balls. In some examples, connectors 113 can have a thickness (height) of approximately 10 μm to approximately 300 μm and a pitch of approximately 10 μm to approximately 300 μm.

In some examples, connectors 113 couple electronic component 110 ca to substrate inward terminals 124a. In some examples, pick-and-place equipment can pick up electronic component 110 and place electronic component 110 on substrate inward terminals 124a on substrate first side 121. Connectors 113 can be coupled to the substrate inward terminals 124a using, for example, a reflow process, a thermal ultrasonic compression method, or a laser assist bonding method. In some examples, electronic component 110 can be located at a central portion or region of substrate first side 121. Electronic component 110 can comprise or be referred to as a die, a chip, or a package. In some examples, electronic component 110 can comprise an active component or a passive component. In some examples, electronic component 110 can comprise a digital signal processor (DSPs), a network processor, a power management unit, an audio processor, a wireless baseband system on a chip (SoC) processor, a sensor, an application specific integrated circuit, a memory, an antenna on package (AoP), an antenna in package (AiP), a 5G NR mmWave module, a sub-6 GHz RF module, a sensor, an integrated passive device (IPD), or other devices as known to one of ordinary skill in the art. In some examples, the overall thickness of electronic component 110 can range from about 40 μm to about 1000 μm, and the area (or “footprint”) of electronic component 110 can range from about 1.0 mm×1.0 mm to about 70 mm×70 mm. The footprint of electronic component 110 is an example of a first footprint.

Electronic component 110′ can comprise component first (or bottom) side 111′ and component second (or top) side 112′. Component first side 111′ can be oriented toward substrate first side 121. Electronic component 110′ can comprise connectors 113′, w In some examples, electronic component 110′ including connectors 113′ can have elements, features, materials, or manufacturing methods similar to those of electronic component 110 including connectors 113. In some examples, electronic component 110′ can be comprise a stacked module, a multichip package, a high bandwidth memory (HBM), or other devices as known to one of ordinary skill in the art. In some example, thickness of electronic components 110′ can range from approximately 40 μm to approximately 1000 μm. In some examples, electronic component 110 is placed in a central portion or location on substrate first side 121 and electronic components 110′ are placed around including surrounding electronic component 110. Electronic components 110 and 110′ can, for example, perform various calculations and control processing, store data, remove noise from an electrical signal, or transmit/receive radio frequencies. In some examples, electronic components 110′ each comprise a footprint. The footprint of electronic component 110′ is an example of a second footprint. In accordance with some examples, the footprint of electronic component 110 (e.g., first footprint) can be greater than the footprint of electronic component 110′ (e.g., second footprint).

FIG. 2C shows a cross-sectional view of electronic device 100 at a later stage of manufacture. In the example shown in FIG. 2C, underfill material 130 can be provided between substrate 120 and electronic component 110, and between substrate 120 and electronic components 110′. Underfill material 130 can comprise or be referred to as a capillary underfill, a no-flow underfill (also called a non-conductive paste (NCP)), a wafer level underfill (also called a B-stage underfill), and a non-conductive film (NCF), or an anisotropic conductive film (ACF). In some examples, underfill material 130 can comprise epoxy, a thermoplastic material, a thermosetting material, polyimide, polyurethane, a polymeric material, filled epoxy, a filled thermoplastic material, a filled thermosetting material, filled polyimide, filled polyurethane, a filled polymeric material, or a fluxing underfill.

In some examples, after electronic components 110 and 110′ are coupled to substrate 120, underfill material 130 can be injected into a gap between electronic components 110 and 110′, and substrate 120 (e.g., capillary underfill). In some examples, underfill material 130 can be applied to substrate 120 and then electronic components 110 and 110′ can be pressed into underfill material 130 (e.g., no-flow underfill). In some examples, underfill material 130 can be applied onto connectors 113 of electronic components 110 and 110′, and then electronic components 110 and 110′ can be attached to substrate 120 while pressing underfill material 130 against substrate 120 (e.g., wafer level underfill). In some examples, underfill material 130 can be positioned on substrate inward terminal 124a of substrate 120 in the form of a film, and after electronic components 110 and 110′ are pressed, an underfill curing process can be performed (e.g., a non-conductive film (NCF)). In this way, underfill material 130 can be positioned between electronic components 110 and 110′ and substrate 120 to wrap or surround connectors 113 and 113′ so that electronic components 110 and 110′ and substrate 120 can be coupled to each other. Underfill material 130 contacts substrate first side 121 of substrate 120 and component first sides 111 and 111′ of electronic components 110 and 110′. Underfill material 130 can redistribute stress and strain due to a difference in the coefficient of thermal expansion between electronic components 110 and 110′ (e.g., CTE: 2-4 ppm/° C.) and substrate 120 (e.g., CTE: 20-30 ppm/° C.), can prevent moisture penetration, can prevent a physical or chemical impact from being transmitted to electronic components 110 and 110′ and can rapidly transfer heat of electronic components 110 and 110′ outward.

FIG. 2D shows a cross-sectional view of electronic device 100 at a later stage of manufacture. In the example shown in FIG. 2D, stiffener 140 can be provided on substrate 120. In some examples, stiffener 140 can be provided on substrate first side 121. The location of stiffener 140 can correspond to a peripheral portion or edge portion of substrate 120. For example, stiffener 140 can be located closer to the lateral sides of substate 120, as compared to electronic components 110 and 110′ so that electronic components 110 and 110′ are inside the perimeter defined by stiffener 140. Stiffener 140 can be provided in a ring shape, such as a square ring shape in a top plan view. In some examples, stiffener 140 can be laterally spaced apart from the lateral sides of electronic components 110 and 110′ so that a portion of substrate first side 121 is exposed between the inner wall of stiffener 140 and the outermost lateral sides of electronic components 110′.

In some examples, stiffener 140 can be coupled to substrate 120 using stiffener adhesive 145. Stiffener adhesive 145 is interposed between the bottom side of stiffener 140 and substrate first side 121. Stiffener adhesive 145 can be provided on substrate first side 121 or on the bottom side of stiffener 140. Stiffener adhesive 145 can comprise an adhesive paste, adhesive, tape, or film. In some examples, stiffener adhesive comprises a thermally conductive and electrically insulative material. Stiffener adhesive 145 can be applied to substrate first side 121 or the bottom side of stiffener 140 by, for example, dispensing or printing techniques, or can be attached in the form of a film. In some examples, the thickness of stiffener adhesive 145 can be between 10 μm and 300 μm.

Stiffener 140 can comprise an inner wall oriented toward electronic components 110 and 110′, and an outer wall opposite to the inner wall. In some examples, the inner wall and the outer wall of stiffener 140 can be a continuous or uninterrupted wall structure. In other examples, the inner walls and the outer walls can comprise separated or spaced apart segmented wall portions (i.e., stiffener 140 can comprise a discontinuous structure). In some examples, the inner wall of stiffener 140 can be laterally spaced apart from the side walls of electronic components 110 and 110′. In some examples, the outer wall of stiffener 140 can be spaced laterally inward from the lateral side of substrate 120 so that a portion of substrate first side 121 is exposed between the outer wall of stiffener 140 and the lateral side of substrate 120. In accordance with the present description, this placement facilitates the formation of encapsulant 150 along the outer wall of stiffener 140, which improves the attachment integrity between encapsulant 150, stiffener 140 and substrate 120. In some examples, the outer wall of stiffener 140 can be closer to electronic components 110′ than to the lateral side of substrate 120.

In some examples, stiffener 140 can comprise or be referred to as a brace, a support, a reinforcement, a rib, or a protuberance. In some examples, stiffener 140 can comprise a conductor. For example, stiffener 140 can comprise stainless steel (SUS), copper, a copper alloy, aluminum, an aluminum alloy, gold, a gold alloy, silver, a silver alloy, nickel, a nickel alloy, palladium, a palladium alloy, or tin silver. In some examples, stiffener 140 can comprise a dielectric, glass, ceramic, or organic material. For example, stiffener 140 can comprise PI, BCB, PBO, ABF or resin. In some examples, the thickness of stiffener 140 can be less than the thicknesses of electronic components 110 and 110′. For example, the thickness of stiffener 140 can be in a range from approximately 38 μm to approximately 990 μm. In some examples, the lateral width of stiffener 140 can be in a range from approximately 0.5 mm to approximately 15 mm. In other examples, the width of stiffener 140 can be in a range from approximately 1.0 mm to approximately 10.0 mm. In other examples, the lateral width of stiffener 140 can be in a range from approximately 1.1 mm to approximately 8.0 mm. It is understood that the lateral width of stiffener 140 is dependent on the package body size and these ranges are only exemplary.

FIG. 2E shows a cross-sectional view of electronic device 100 at a later stage of manufacture. In the example shown in FIG. 2E, substrate 120 can be coupled to a carrier 10. In some examples, electronic device subassembly 100A, provided with stiffener 140 and electronic components 110 and 110′ on substrate first side 121, can be attached or fixed to carrier 10. Electronic device subassembly 100A can be an electronic device manufactured by the example manufacturing process of FIGS. 2A to 2D. In some examples, carrier 10 can comprise a temporary adhesive layer 10a provided on an upper side of carrier 10 and electronic device subassembly 100A can be attached to temporary adhesive layer 10a. In some examples, a plurality of electronic devices subassemblies 100A can be attached to carrier 10 and laterally spaced apart from each other to provide a gap or void between adjacent electronic devices subassemblies 110A.

In some examples, carrier 10 can be a substantially planar plate. In some examples, carrier 10 can comprise or be referred to as a substrate, plate, a board, a wafer, a panel, or a strip. In some examples, carrier 10 can be provided as a wafer, such as a semiconductor wafer or substrate. In some examples, the thickness of carrier 10 can range from approximately 100 μm to approximately 2000 μm, and the width of carrier 10 can range from approximately 100 mm to approximately 320 mm. Carrier 10 can serve to enable handling of multiple subassemblies or components during manufacturing.

In some examples, temporary adhesive layer 10a can be provided on the upper side of carrier 10. Temporary adhesive 10a can be provided using a coating method, such as spin coating, doctor blade coating, casting, painting, spray coating, slot die coating, curtain coating, slide coating, or knife over edge coating, a printing method such as screen printing, pad printing, gravure printing, flexography printing, or offset printing, or an inkjet printing method, an intermediate technology between coating and printing, or can be provided by direct attachment of a bonding film or bonding tape. In some examples, temporary adhesive layer 10a can comprise or be referred to as a temporary bonding film, a temporary bonding tape or a temporary adhesive coating. In some examples, temporary adhesive layer 10a can be a heat release tape (film) or an optical release tape (film), configured so that the adhesive strength is reduced by heat or light. Temporary adhesive layer 10a can be configured to facilitate the separation of carrier 10 and substrate 120.

FIG. 2F shows a cross-sectional view of electronic device 100 at a later stage of manufacture. In the example shown in FIG. 2F, encapsulant 150 can be provided on electronic components 110 and 110′, substrate 120, underfill material 130, and stiffener 140. Encapsulant 150 can contact, cover, embed, or encapsulate electronic components 110 and 110′, substrate 120, underfill material 130, and stiffener 140. For example, encapsulant 150 can be in contact including direct contact with component second side 112 and component lateral sides of electronic components 110 and 110′, substrate first side 121 and the lateral sides of substrate 120, the lateral sides of underfill material 130, and the top side, inner wall and outer wall of the stiffener 140.

In some examples, encapsulant 150 can comprise or be referred to as an epoxy mold compound, a resin, a sealant, a filler-reinforced polymer, a B-stage pressed film, a gel, or an organic body. In some examples, encapsulant 150 can comprise an epoxy or phenol resin, carbon black and a silica filler. In some examples, encapsulant 150 can be provided by compression molding, transfer molding, liquid encapsulant molding, vacuum lamination, paste printing, film assist molding, or any other suitable deposition technique. The compression molding can be performed by supplying flowable resin to a mold in advance, placing a substrate into the mold, and then curing the flowable resin. Transfer molding can be performed with flowable resin supplied from a gate (supply port) of a mold to the periphery of an electronic component and then cured. The thickness of encapsulant 150 can range from approximately 100 μm to approximately 2000 μm. In some examples, encapsulant 150 comprises a thickness sufficient to completely cover or embed electronic components 110′ and completely cover or embed stiffener 140 in the finished electronic device 100.

Encapsulant 150 can provide protection for electronic components 110 and 110′ from external elements or environmental exposure and can rapidly emit heat generated from electronic components 110 and 110′. In some examples, encapsulant 150 can be in the gap or vertical space between electronic components 110 and 110′ and substrate 120. For example, encapsulant 150 can replace underfill material 130 and underfill material 130 can be omitted (e.g., encapsulant 150 can be molded underfill).

FIG. 2G shows a cross-sectional view of electronic device 100 at a later stage of manufacture. In the example shown in FIG. 2G, an upper portion of encapsulant 150 can be removed to reduce its thickness and define the top side encapsulant 150 for electronic device 100. In some examples, this step can be done while carrier 10 is attached to substrate 120. In some examples, a grinding or an etching process can be used to remove the upper portion of encapsulant 150. In some examples, the upper portion of encapsulant 150 can be removed until component second sides 112 and 112′ of electronic components 110 and 110′ are exposed from the top side of encapsulant 150. Encapsulant 150 remains interposed between the lateral sides of adjacent electronic components 110 and 110′. In some examples, component second sides 112 and 112′ of electronic components 110 and 110′ and the top side of encapsulant 150 can be substantially coplanar after the removal process. In other examples, electronic components 110′ remain covered by encapsulant 150 so that electronic components 110′ are not exposed from the top side of encapsulant 150. In the present example, encapsulant 150 covers the outer wall, the inner wall, and the top side of stiffener 140 to completely embed stiffener 140 within or inside of encapsulant 150. In some examples, no portion of outer wall, inner wall, or the top side of stiffener 140 is exposed from encapsulant 150. In other examples, the encapsulant removal process can be omitted and encapsulant 150 can be provided with component second sides 112 and 112′ of electronic components 110 and 110′ exposed from the top side of encapsulant 150 as part of the molding process.

In some examples, the thickness of encapsulant 150 located on or overlying the top side of stiffener 140 can be in a range from approximately 10 μm to approximately 600 μm. In some examples, the thickness of encapsulant 150 located on or overlying the top side of stiffener 140 is greater than approximately 50 μm, which was found through experimentation to decrease occurrences of encapsulant 150 separating from stiffener 140. In some examples, the thickness of encapsulant 150, as measured from substrate first side 121, can be similar to the thickness of electronic components 110 and 110′. For example, the thickness of encapsulant 150 can be in a range from approximately 100 μm to approximately 900 μm.

In some examples, a conductor or metallization can be provided on component second sides 112 and 112′ of electronic components 110 and 110′ at this stage of manufacture. In some examples, the conductor can also be provided on the top side of encapsulant 150. In some examples, the conductor can be a continuous structure across the top side of encapsulant 150 and component second sides 112 and 112′ of electronic components 110 and 110′. In some examples, the conductor can comprise Ti, Cu, Ni, or SnAg. In some examples, the metallization layer can also comprise Ni, Cu, In, Au, or Ag. In some examples, the conductor can be configured to enhance heat transfer away from electronic components 110 and 110′ and can enhance the adhesion of other elements to electronic components 110 and 110′, such as thermal interface material (TIM) layers or heat sinks.

In some examples, after the upper portion of encapsulant 150 is removed, electronic device 100 can undergo a singulation process where encapsulant 150 and substrate 120 are separated into individual electronic devices 100. In some examples, the singulation process can utilize a blade, laser beam, an etchant, or other suitable singulation tool. In accordance with the present description, since stiffener 140 is inset from the singulation lines that form the lateral sides of substrate 120, the singulation process does not singulate through stiffener 140 and encapsulant 150 remains to cover the outer wall of stiffener 140. In the singulation process, the separation extends through encapsulant 150 to provide individual electronic devices 100. The singulation process defines the lateral sides of encapsulant 150, which can comprise or be referred to as encapsulant lateral sides. In the present example, encapsulant 150 covers and overlaps the lateral sides of substrate 120. In some examples, carrier 10 can then be removed to expose substrate second side 122 of substrate 120.

FIG. 2G-1 illustrates a cross-sectional view of an alternative embodiment of electronic device 100. In the present example, substrate 120 can be provided as a panel, array, plurality, or matrix of substrates 120. In other examples, substrate 120 can be provided as an RDL substrate with multiple substrates 120 in an array or matrix configuration. In the present example, encapsulant 150 is not disposed or provided along the lateral sides of the individual substrates 120 but is provided along the outer wall of stiffener 140. In the singulation process, the separation extends through encapsulant 150 and substrates 120 to provide individual electronic devices 100. In the present example, the lateral sides of encapsulant 150 are coplanar with the lateral sides of substrate 120.

FIG. 2H shows a cross-sectional view of electronic device 100 at a later stage of manufacture. In the example shown in FIG. 2H, lid 160 can be provided on the top side of encapsulant 150 and on component second sides 112 and 112′ of electronic components 110 and 110′. In some examples, lid 160 extends to overlie the top side of stiffener 140 but is separated from the top side of stiffener 140 by encapsulant 150 (and lid adhesive 165) In some examples, lid 160 can comprises a substantially square plate and can cover encapsulant 150 and electronic components 110 and 110′. In some examples, lid 160 can completely cover encapsulant 150 and electronic components 110 and 110′ and extends to completely overlie stiffener 140. Lid 160 and component second sides 112 and 112′ of electronic components 110 and 110′, and lid 160 and encapsulant 150 can be attached and fixed through lid adhesive 165. For example, lid adhesive 165 can comprise or be referred to as an attachment material, adhesive material, thermal interface material (TIM), or solder. In some examples, lid adhesive 165 can comprise or be referred to as a TIM. Lid adhesive 165 can comprise a thermally conductive and electrically insulative material and can be in contact with component second sides 112 and 112′ of the electronic components 110 and 110′ and the bottom side of the lid 160. In some examples, lid adhesive 165 comprises polymer type thermal interface materials, such as silicone, epoxy, or urethane with highly thermal conductive fillers, such as graphite, boron nitride, silver, aluminum, or aluminum oxide. Since lid adhesive 165 comprises a thermally conductive material, heat generated from electronic components 110 and 110′ can be more effectively transferred to lid 160.

Lid 160 can comprise a conductor, such as a metal with high heat conduction and radiation. In some examples, lid 160 can comprise aluminum, copper, or alloys. In some examples, lid 160 can comprise or be referred to as a heat sink, heat sink, cap cover, encapsulation portion, protective portion, package, or body. In some examples, lid 160 can comprise a trench, protrusion, or fin on the top side to improve heat dissipation efficiency. In some examples, the thickness of lid 160 can be in a range from approximately 300 μm to approximately 3000 μm.

FIG. 2I shows a cross-sectional view of electronic device 100 at a later stage of manufacture. In the example shown in FIG. 2I, external interconnects 170 can be provided on substrate second side 122 of substrate 120.

External interconnects 170 can be coupled to conductive structure 124 exposed from substrate second side 122 of substrate 120. In some examples, external interconnects 170 can be coupled to substrate outward terminals 124b of conductive structure 124. In some examples, external interconnects 170 can comprise or be referred to as solder balls, solder coated metal (e.g., copper) core balls, pillars, pillars with solder caps, or bumps with solder caps. External interconnects 170 can comprise Sn, Ag, Pb, Cu, Sn—Pb, Sn37-Pb, Sn95-Pb, Sn—Pb—Ag, Sn—Cu, SnAg, Sn—Au, Sn—Bi, or SnAg—Cu. In some examples, external interconnects 170 can be provided through a reflow process after forming a conductive material including solder on substrate second side 122 in a ball drop method. External interconnects 170 can be used to couple electronic device 100 to an external device, such as printed circuit board or another electronic device. In some examples, the thickness of each of external interconnects 170 can range from about 25 μm to about 1000 μm and external interconnects 170 can have a pitch of between about 25 μm to about 1000 μm. In other examples, external interconnects 170 are not used and electronic device 100 can comprise a Land Grid Array (LGA) configuration.

In some examples, electronic components 180 can be provided on substrate second side 122 of substrate 120. Electronic components 180 are an example of bottom side electronic components. Electronic components 180 can comprise passive or active components and can be coupled to substrate outward terminals 124b of substrate 120 laterally between external interconnects 170. In some examples, electronic component 180 comprise an antenna patch or an integrated passive device (IPD). In some examples, electronic components 180 can be dies, chips, or packages. In some examples, electronic components 180 can be thinner than external interconnects 170. For example, electronic components 180 can have a thickness in a range from approximately 10 μm to approximately 500 μm.

FIG. 2I-1 illustrates a cross-sectional view of the alternative embodiment of electronic device 100 of FIG. 2G-1. In the present example, lid 160 is provided coupled to encapsulant 150 with lid adhesive 165. In some examples, external interconnects 170 are coupled to substrate second side 122 as described with FIG. 2I. In some examples, electronic components 180 can be coupled to substrate second side 122. In the present example, the lateral sides of encapsulant 150 are coplanar with the lateral sides of substrate 120. In some examples, lid 160 can be provided as a panel that extends over a plurality of electronic devices 100 and the singulation process can include singulating through the panel to provide individual lids 160. In some examples, the singulation process comprises singulating through the panel, lid adhesive 165, encapsulant 150, and substrate 120. In the present example, encapsulant 150 completely covers the outer wall of stiffener 140.

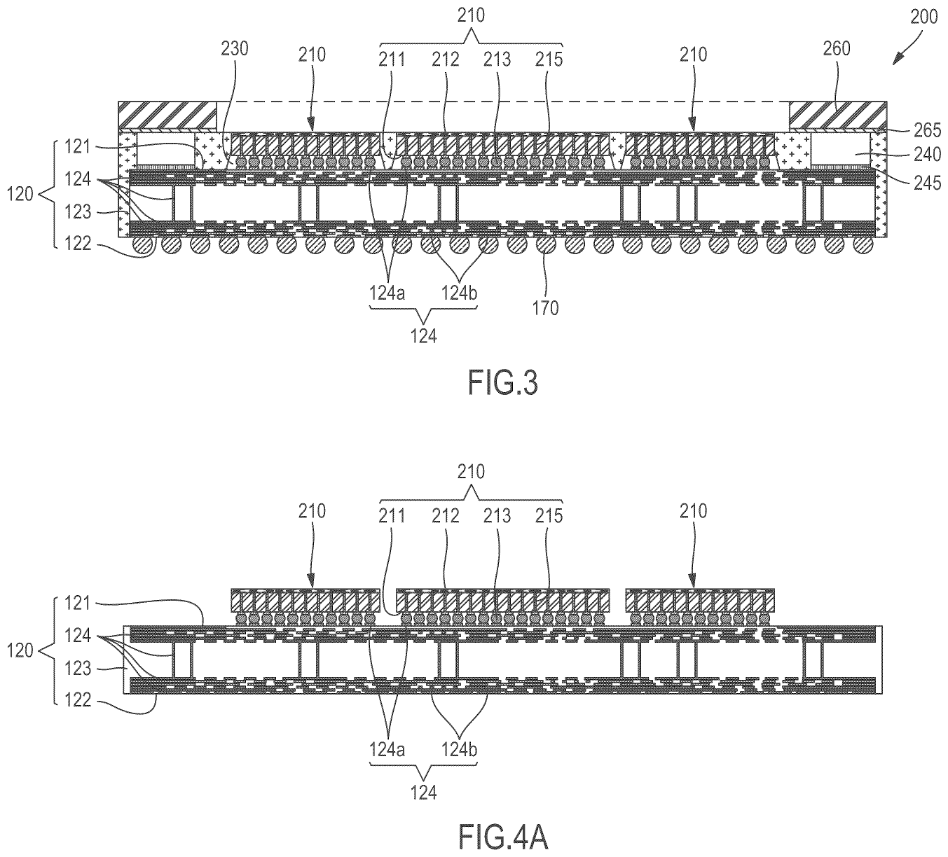

FIG. 3 shows a cross-sectional view of an electronic device 200. In the present example, electronic device 200 comprises electronic components 210, substrate 120, underfill material 230, stiffener 240, encapsulant 250, lid 260, and external interconnects 170. Electronic device 200 has some similarity in construction to electronic device 100 in FIG. 1 including substrate 120, and such similarity will not be repeated here. In this regard, only the distinctions between the two electronic devices will be discussed hereinafter. Although electronic device 200 is shown with three electronic components 210, it is understood that more or less than three electronic components 210 can be included with electronic device 200. In addition, other die, chips, or packages may be included on substrate 120 as part of electronic device 200.

In some examples, electronic components 210 can each comprise a component first side 211, a component second side 212 opposite to component first side 211, and connectors 213 proximate to component first side 211. A component lateral side connects component first side 211 to component second side 212. In some examples, one or more electronic components 210 can comprise through-silicon vias (TSVs) extending between component first side 211 and component second side 212. Stiffener 240 can comprise stiffener adhesive 245 and lid 260 can comprise lid adhesive 265. Stiffener 240 is an example of a thermal stress reducing structure. Stiffener 240 is an example of a first stiffener. In the present example, the outer wall and the inner wall of stiffener 240 are embedded within or inside of encapsulant 250.

Substrate 120, underfill material 230, stiffener 240, encapsulant 250, lid 260, and external interconnects 170 can be referred to as an electronic package or a package. The electronic package can provide protection for electronic components 210 from external elements or environmental exposure. The electronic package can also provide electrical coupling between electronic components 210 or between electronic components 210 and an external component or other electronic packages.

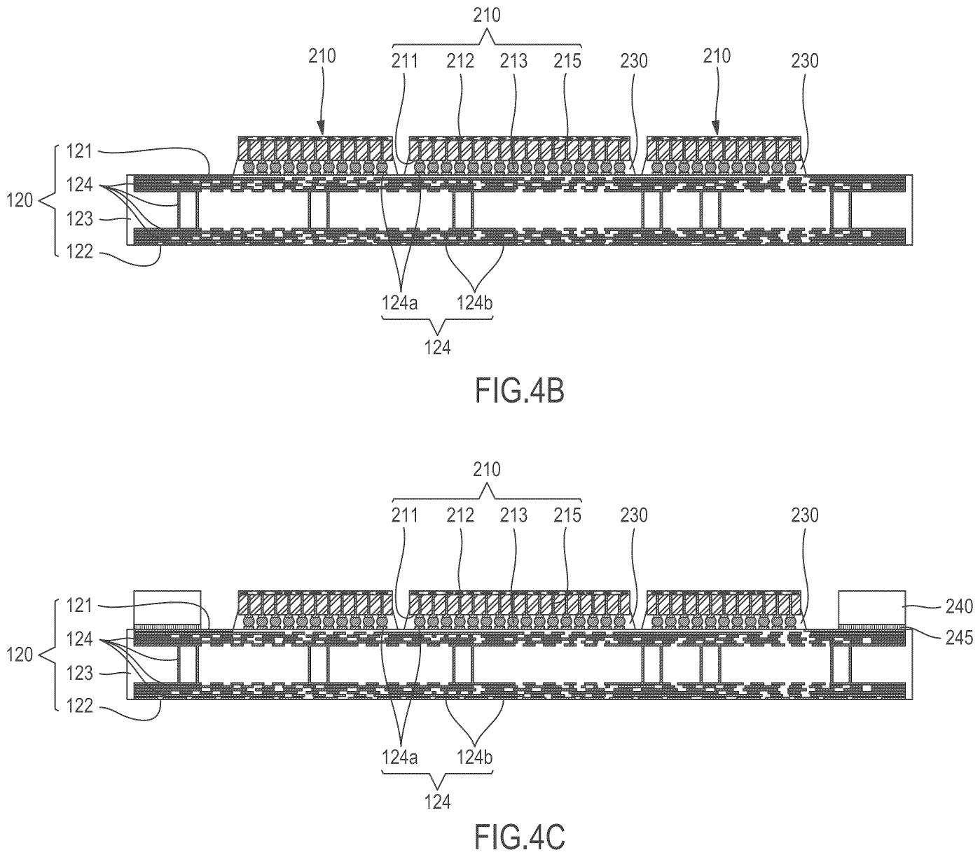

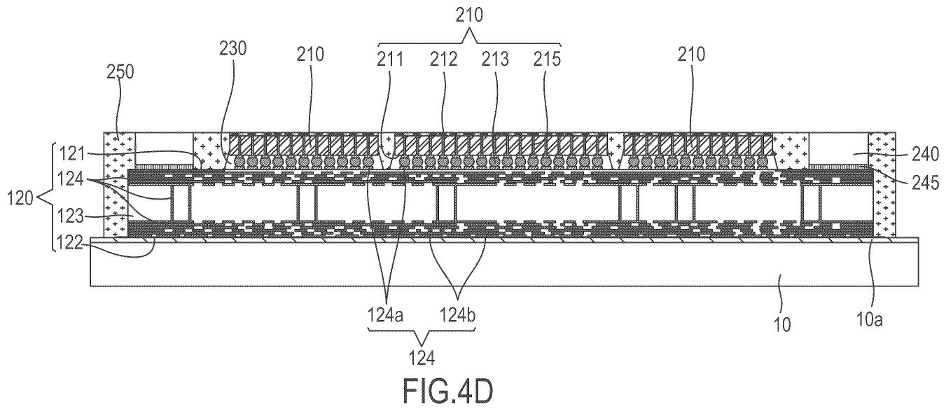

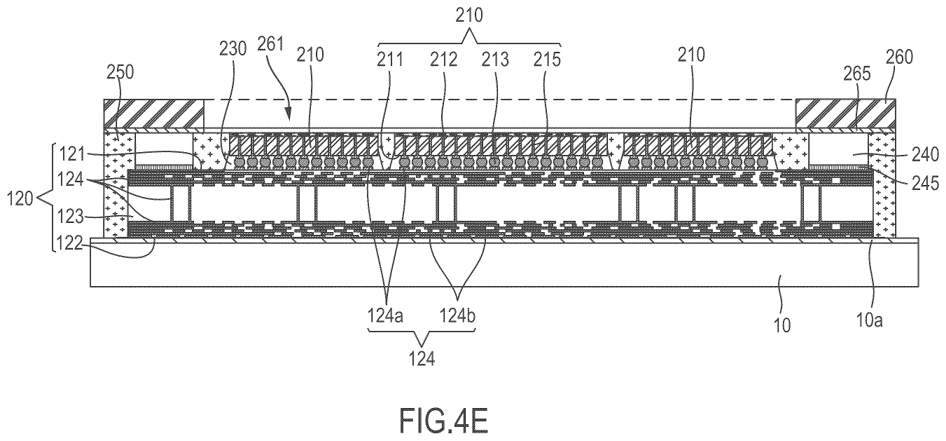

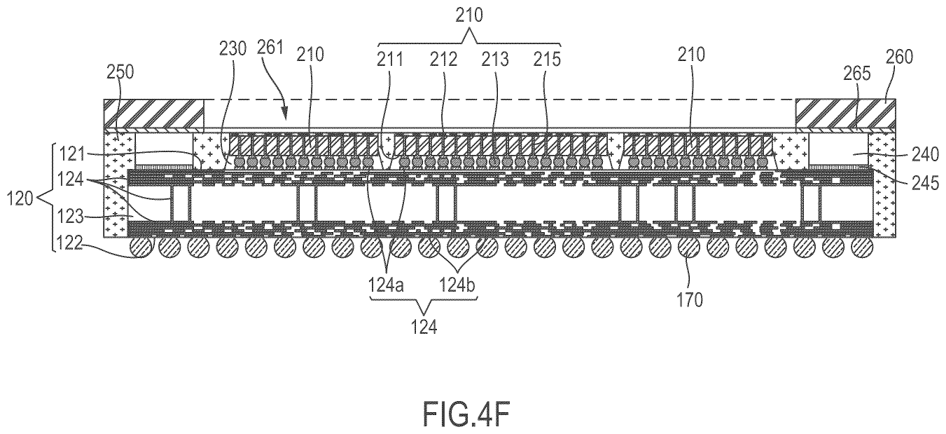

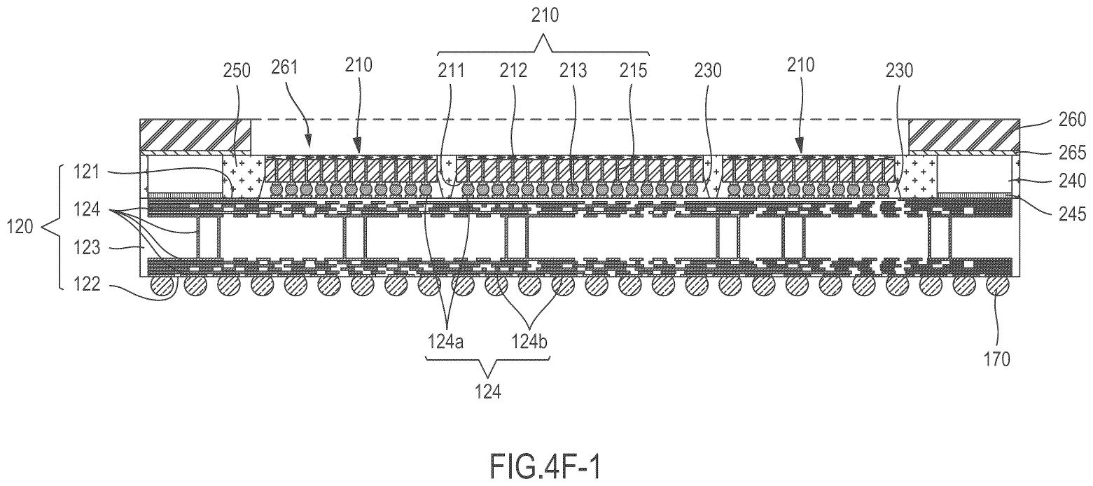

FIGS. 4A, 4B, 4C, 4D, 4E, 4F, and 4F-1 show cross-sectional views of an example method for manufacturing an electronic device, such as electronic device 200. The example method for manufacturing the electronic device 200 shown in FIGS. 4A to 4F-1 can be similar to the example method for manufacturing the example electronic device 100 shown in FIGS. 2A to 2I-1.

FIG. 4A shows a cross-sectional view of electronic device 200 at an early stage of manufacture. In the example shown in FIG. 4A, electronic components 210 can be provided on substrate first side 121. The elements, features, materials, or manufacturing methods of substrate 120 of electronic device 200 can be similar to, or the same as, those of substrate 120 of electronic device 100. In some examples, substrate 120 of electronic device 200 comprises a thin core or a coreless substrate as described previously.

Electronic components 210 can comprise component first sides 211, component second sides 212, and component lateral sides connecting component first sides 211 to component second sides 212. In some examples, component first sides 211 can be active sides and can face substrate first side 121. Electronic components 210 can also comprise connectors 213 coupling electronic components 210 to substrate 120. Connectors 213 can comprise or be referred to as a contact pad, a bump, a SnPb bump, a lead-free bump, a copper post, a copper pillar, or a stud bump connecting electronic components 210 to substrate 120. Elements, features, materials, or manufacturing methods of electronic components 210 of electronic device 200 can be similar to, or the same as, those of electronic component 110 of electronic device 100 described previously.

In some examples, electronic components 210 can be provided with a redistribution structure including a conductive structure and a dielectric structure on component second sides 212. In some examples, electronic components 210 can comprise through-silicon vias (TSVs) 215 passing between component first sides 211 and component second sides 212 of electronic components 210. Through-silicon vias 215 can electrically connect the conductive structure of the redistribution structure on component second side 212 of electronic component 210 and connectors 213 on component first side 211. In some examples, the thickness of electronic components 210 can be in a range from approximately 40 μm to approximately 1000 μm.

FIG. 4B shows a cross-sectional view of electronic device 200 at a later stage of manufacture. In the example shown in FIG. 4B, underfill material 230 can be provided between component first sides 211 of electronic components 210 and substrate first side 121. The elements, features, materials, or manufacturing methods of underfill material 230 of electronic device 200 can be similar to, or the same as, those of underfill material 130 of electronic device 100 described previously.

In some examples, after electronic components 210 are coupled to substrate 120, underfill material 230 can be injected into a gap between electronic components 210, and substrate 120 (e.g., capillary underfill). In some examples, underfill material 230 can be applied to substrate 120 and then electronic components 210 can be pressed into underfill material 230 (e.g., no-flow underfill). In some examples, underfill material 230 can be applied onto connectors 213 of electronic components 210, and then electronic components 210 can be attached to substrate 120 while pressing underfill material 230 against substrate 120 (e.g., wafer level underfill). In some examples, underfill material 230 can be positioned on substrate inward terminal 124a of substrate 120 in the form of a film, and after electronic components 210 are pressed, an underfill curing process can be performed (e.g., a non-conductive film (NCF)). In this way, underfill material 230 can be positioned between electronic components 210 and substrate 120 to wrap or surround connectors 213 so that electronic components 210 and substrate 120 can be coupled to each other. Underfill material 230 contacts substrate first side 121 of substrate 120 and component first sides 211 of electronic components 210. Underfill material 230 can redistribute stress and strain due to a difference in the coefficient of thermal expansion between electronic components 210 (e.g., CTE: 2-4 ppm/° C.) and substrate 120 (e.g., CTE: 20-30 ppm/° C.), can prevent moisture penetration, can prevent a physical or chemical impact from being transmitted to electronic components 210 and can rapidly transfer heat of electronic components 210 outward. In some examples, underfill material 230 is not used. In some examples, encapsulant 250 can fill the gap between component first sides 211 and substrate first side 121 as described previously with encapsulant 150.

FIG. 4C shows a cross-sectional view of electronic device 200 at a later stage of manufacture. In the example shown in FIG. 4C, stiffener 240 can be provided on substrate 120. In some examples, stiffener 240 can be provided on substrate first side 121. In some examples, stiffener 240 can be attached to substrate first side 121 with stiffener adhesive 245. The location of stiffener 240 can correspond to a peripheral portion or edge portion of substrate 120. For example, stiffener 240 can be located closer to the lateral sides of substrate 120, as compared to electronic components 210 so that electronic components 210 are inside the perimeter defined by stiffener 240. Stiffener 240 can be provided in a ring shape, such as a square ring shape in a top plan view. In some examples, stiffener 240 can be laterally spaced part from the lateral sides of electronic components 210 so that a portion of substrate first side 121 is exposed between the inner wall of stiffener 240 and the outermost lateral sides of electronic components 210.

In some examples, after stiffener adhesive 245 is provided on substrate first side 121, stiffener 240 can be provided on the top side of stiffener adhesive 245. Stiffener adhesive 245 can be interposed between the bottom side of stiffener 240 and substrate first side 121. The elements, features, materials, or manufacturing methods of stiffener 240 of electronic device 200 can be similar to, or the same as, those of stiffener 140 of electronic device 100. In some examples, stiffener 240 can be made of a grindable dielectric material or another material that facilitates the partial removal of an upper part of stiffener 240 at a subsequent process step. For example, stiffener 240 can comprise a dielectric or inorganic material such as PI, BCB, PBO, ABF, or resin. Stiffener 240 can be made of a grindable metal or an alloy material. In some examples, the starting or as provided thickness of stiffener 240 can be greater than the thickness of electronic components 210. For example, the starting thickness of stiffener 240 can be approximately 50 μm to 1010 μm. In some examples, the lateral width of stiffener 240 can be in a range from approximately 0.5 mm to approximately 15 mm. In other examples, the width of stiffener 240 can be in a range from approximately 1.0 mm to approximately 10.0 mm. In other examples, the lateral width of stiffener 240 can be in a range from approximately 1.1 mm to approximately 8.0 mm. It is understood that the lateral width of stiffener 240 is dependent on the package body size and these ranges are only exemplary. The elements, features, materials, or manufacturing methods of stiffener adhesive 245 of electronic device can be similar to or the same as those of stiffener adhesive 145 of electronic device 100 as described previously.

FIG. 4D shows a cross-sectional view of electronic device 200 at a later stage of manufacture. In the example shown in FIG. 4D, substrate 120 can be coupled to carrier 10. In some examples, electronic device 200 provided with stiffener 240 and electronic components 210 on the upper side of substrate 120, can be attached and fixed on carrier 10. In some examples, carrier 10 can comprise a temporary adhesive layer 10a provided on an upper side of carrier 10 and electronic device 200 can be attached to temporary adhesive layer 10a. In some examples, a plurality of electronic devices 200 can be attached to carrier 10 and laterally spaced apart from each other to provide a gap or void between adjacent electronic devices 200. The elements, features, materials, or manufacturing methods of carrier 10 and temporary adhesive layer 10a can be similar to or the same as those described previously with electronic device 100. Carrier 10 can serve to enable handling of multiple devices or components during manufacturing.

In the example shown in FIG. 4D, after substrate 120 is coupled to carrier 10, encapsulant 250 can be provided on substrate first side 121, electronic components 210, underfill material 230, and stiffener 240. In some examples, encapsulant 250 can contact including directly contact, cover, embed, or encapsulate lateral sides of electronic components 210, substrate first side 121, the lateral sides of underfill material 230, the outer wall of stiffener 240, and the inner wall of stiffener 240. Encapsulant 250 can have corresponding elements, features, materials, or manufacturing methods similar to those of encapsulant 150 of electronic device 100 as described previously.

In the present example, an upper portion of encapsulant 250 can be removed to reduce its thickness and to define the top side of encapsulant 250. In some examples, a grinding or an etching process can be used to remove the upper portion of encapsulant 250. In the present example, the removal step exposes component second sides 212 of electronic components 210 and the top side of stiffener 240 from the top side of encapsulant 250. In the present example, an upper portion of stiffener 240 is removed during the removal step to define the top side of stiffener 240 and the final thickness of stiffener 240. In the present example, top side of stiffener 240 is an example of a stiffener with a top side that comprises a grinded surface, a mechanically defined surface, or a chemically defined surface where such surfaces can be provided after stiffener 240 is coupled to substrate 120 and covered by encapsulant 250. After the removal step, the top side of encapsulant 250, the exposed component second sides 212 of electronic components 210, and the top side of stiffener 240 can be substantially coplanar. In some examples, the thickness of encapsulant 250, electronic components 210, and stiffener 240 can be similar. In some examples, the lateral sides of encapsulant 250 can cover the lateral sides of substrate 120. In other examples, the lateral sides of encapsulant 250 can be coplanar with the lateral sides of substrate 120 (see e.g., FIG. 4F-1). Carrier 10 can be removed after encapsulant 250 is provided or after the upper portion of encapsulant 250 is removed.

In some examples, after the upper portion of encapsulant 250 is removed, electronic device 100 can undergo a singulation process where encapsulant 250 and substrate 120 are separated into individual electronic devices 200. In accordance with various examples, the singulation process can utilize a blade, laser beam, an etchant, or other suitable singulation tool. In accordance with the present description, since stiffener 240 is inset from the singulation lines that form the lateral sides of substrate 120, the singulation process does not singulate through stiffener 240 and encapsulant 250 remains covering the outer wall of stiffener 240. This improves the attachment integrity between encapsulant 250, substrate 120 and stiffener 240. In the singulation process, the separation extends through encapsulant 250 to provide individual electronic devices 200. The singulation process defines the lateral sides of encapsulant 250, which can comprise or be referred to as encapsulant lateral sides. In the present example, encapsulant 250 covers and overlaps the lateral sides of substrate 120.

FIG. 4E shows a cross-sectional view of electronic device 200 at a later stage of manufacture. In the example shown in FIG. 4E, lid 260 can be provided to cover the top side of stiffener 240. Lid 260 can be provided in a ring shape, such as square ring shape in a top plan view. In the present example, lid 260 covers the top side of stiffener 240 exposed from the top side of encapsulant 250 and covers a portion of the top side of encapsulant 250 adjacent to stiffener 240. In some examples, lid 260 extends laterally to the lateral sides of encapsulant 250 so that the lateral sides of lid 260 are substantially coplanar with the lateral sides of encapsulant 250. The elements, features, materials, or manufacturing methods of lid 260 can be similar to, or the same as, those of lid 160 of electronic device 100 described previously.

The width of lid 260 as defined by the distance from the inner wall to the outer wall of lid 260, can be greater than the width of stiffener 240. Lid 260 can be attached to the top side of encapsulant 250 and the top side of stiffener 240 with lid adhesive 265. For example, lid adhesive 265 can be provided to cover the top side of encapsulant 250 and the top side of stiffener 240, and lid 260 can then be provided on the top side of lid adhesive 265. Lid adhesive 265 can be interposed between lid 260 and stiffener 240 and between lid 260 and encapsulant 250. Elements, features, materials, or manufacturing methods of lid adhesive 265 can be similar to, or the same as, those of lid adhesive 165 of electronic device 100 as described previously.

In some examples, lid 260 can comprise an opening 261 extending between the top side and the bottom side in the central area. Component second sides 212 of electronic components 210 can be exposed from or within opening 261 of lid 260. Opening 261 can comprise or be referred to as an aperture or hole. In some examples, a heat dissipation plate for additional heat dissipation can be provided on component second sides 212 of electronic components 210 exposed from opening 261 of lid 260. In some examples, the additional heat dissipation plate can have trenches, protrusions, or fins. Since lid 260 can be provided to have a greater width than stiffener 240, bending or twisting of electronic device 200 can be alleviated compared to when only stiffener 240 is provided. In some examples, lid 260 can have a width of 1 mm to 30 mm and a thickness of 100 μm to 3000 μm.

In some examples, lid 260 can comprise or be referred to as a metal lid or stiffener. For example, lid 260 can comprise stainless steel (SUS), copper, a copper alloy, aluminum, an aluminum alloy, gold, a gold alloy, silver, a silver alloy, nickel, a nickel alloy, palladium, a palladium alloy, or tin silver. Lid 260 can be an example of a second stiffener or a post-molding stiffener.

FIG. 4F shows a cross-sectional view of electronic device 200 at a later stage of manufacture. In the example shown in FIG. 4F, external interconnects 170 can be provided on substrate second side 122 substrate 120. External interconnects 170 can be coupled to substrate outward terminals 124b of substrate 120. In some examples, LGA can be also possible design. External interconnects 170 can have corresponding elements, features, materials, or manufacturing methods similar to those of external interconnects 170 of electronic device 100 described previously. In some examples, electronic components 180 can be provided on substrate second side 122.

FIG. 4F-1 shows a cross-sectional view of the alternative embodiment of electronic device 200. In the present example, lid 260 is provided coupled to encapsulant 250 with lid adhesive 265. In some examples, external interconnects 170 are coupled to substrate second side 122 as described with FIG. 4F. In the present example, substrate 120 can be provided as a panel, array, plurality, or matrix of substrates 120. In other examples, substrate 120 can be provided as an RDL substrate with multiple substrates 120 in an array or matrix configuration. In the present example, encapsulant 250 is not disposed or provided along the lateral sides of the individual substrates 120 but is provided along the outer walls of stiffener 240. In the singulation process, the separation extends through encapsulant 250 and substrates 120 to provide individual electronic devices 200. In some examples, the singulation process defines the lateral sides of encapsulant 250, which can comprise or be referred to as encapsulant lateral sides, and defines the lateral sides of substrate 120. In the present example, the lateral sides of encapsulant 250 are coplanar with the lateral sides of substrate 120. In the present example, because the outer wall of stiffener 240 is laterally inset from the lateral side of substrate 120, encapsulant 250 covers the outer walls of stiffener 240. This improves the attachment integrity between encapsulant 250, substrate 120 and stiffener 240.

In some examples including the examples of FIG. 4E, 4F, and 4F-1, lid 260 can be provided as a panel that extends over a plurality of electronic devices 200 and the singulation process can include singulating through the panel to provide individual lids 260. In some examples, the singulation process comprises singulating through the panel, lid adhesive 265, encapsulant 250, and substrate 120.

In summary, structures and associated methods that relate to packaged electronic devices that are more resilient to thermal stress have been disclosed herein. More particularly, structures and methods have been described that improve the reliability of packaged electronic devices that reduce defects associated with thermal stress, such warpage, package distortion, bending, component cracking, or delamination. In some examples, a first stiffener is provided at a peripheral edge of a substrate with one or more electronic components placed on the substrate inside the perimeter of the first stiffener. An encapsulant encapsulates the first stiffener and the electronic components. In some examples, lateral sides and the top side of the first stiffener are covered by the encapsulant. In some examples, the lateral sides are covered by the encapsulant and the top side of the first stiffener is exposed from the encapsulant. In some examples, the first stiffener comprises a material that can be selectively removed using, for example, a grinding process. This conveniently sets the thickness of the stiffener after the stiffener is encapsulated. In some examples, component sides of the electronic components can be exposed from the top side of the encapsulant. In some examples, a lid can be coupled to or overlie the stiffener. In some examples, the lid comprises an opening and the components sides are exposed within the opening. In some examples, the lid can be configured as an additional stiffener. The stiffener(s) reduces the occurrence of warpage, package distortion, bending, component cracking, or delamination thereby improving the reliability of the electronic package. In addition, because the lateral sides (including the outer walls) of the stiffener are covered by the encapsulant, the attachment integrity between the encapsulant, the substrate, and the stiffener is improved.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

What is claimed is:

1. An electronic device, comprising:
a substrate comprising:
a substrate first side comprising a peripheral portion and a central portion surrounded by the peripheral portion;
a substrate second side opposite to the substrate first side;
a substrate lateral side;
a dielectric structure; and
a conductive structure;
a first electronic component comprising:
a component first side coupled to the conductive structure at the substrate first side of the substrate in the central portion;
a component second side opposite to the component first side; and
a component lateral side connecting the component first side to the component second side;
a stiffener coupled to the substrate first side in the peripheral portion and comprising:
an inner wall;
an outer wall opposite to the inner wall; and
a top side; and
an encapsulant covering the inner wall, the outer wall, and the component lateral side, and a portion of the substrate first side, wherein the component second side is exposed from a top side of the encapsulant.

2. The electronic device of claim 1, further comprising:
a lid coupled to the top side of the encapsulant.

3. The electronic device of claim 2, wherein:
the lid comprises an opening; and
the component second side is exposed from the opening.

4. The electronic device of claim 2, further comprising:
a thermal interface material (TIM), wherein:
the lid is attached to the top side of the encapsulant with the TIM.

5. The electronic device of claim 1, wherein:
the encapsulant covers the top side of the stiffener.

6. The electronic device of claim 5, wherein:
the encapsulant comprises a first thickness over the top side of the stiffener; and
the first thickness is greater than approximately 50 microns.

7. The electronic device of claim 1, wherein:
the top side of the stiffener is exposed from the top side of the encapsulant; and
the top side of the stiffener, the top side of the encapsulant, and the component second side of the first electronic component are substantially coplanar.

8. The electronic device of claim 7, wherein:
the top side of the stiffener comprises a grinded surface.

9. The electronic device of claim 1, further comprising:
a second electronic component coupled to the conductive structure in the central portion, wherein:
the second electronic component is interposed between the first electronic component and the stiffener;
the first electronic component comprises a first footprint;
the second electronic component comprises a second footprint; and
the first footprint is larger than the second footprint.

10. The electronic device of claim 1, wherein:
the encapsulant comprises an encapsulant lateral side; and
the encapsulant lateral side overlaps the substrate lateral side.

11. The electronic device of claim 1, wherein:
the encapsulant comprises an encapsulant lateral side; and
the encapsulant lateral side is substantially coplanar with the substrate lateral side.

12. An electronic device, comprising:
a substrate comprising:
a substrate first side comprising a peripheral portion and a central portion surrounded by the peripheral portion;
a substrate second side opposite to the substrate first side;
a substrate lateral side;
a dielectric structure; and
a conductive structure;
a first electronic component comprising:
a component first side coupled to the conductive structure at the substrate first side of the substrate in the central portion;
a component second side opposite to the component first side; and
a component lateral side connecting the component first side to the component second side;
a stiffener coupled to the substrate first side in the peripheral portion and comprising:
an inner wall;
an outer wall opposite to the inner wall and laterally inset from the substrate lateral side; and
a top side;
an encapsulant covering the inner wall, the outer wall, and the component lateral side, and a portion of the substrate first side; and
a lid coupled to the top side of the encapsulant.

13. The electronic device of claim 12, wherein:
the lid comprises an opening; and
the component second side is exposed from a top side of the encapsulant and exposed within the opening.

14. The electronic device of claim 12, further comprising:
a thermal interface material (TIM), wherein:
the lid is attached to the top side of the encapsulant with the TIM.

15. The electronic device of claim 12, wherein:
the substrate comprises a thin core; and
the thin core comprises a thickness in range from approximately 0.5 millimeters (mm) to approximately 1.2 mm.

16. The electronic device of claim 12, wherein:
the substrate comprises a coreless substrate; and
the coreless substrate comprises a thickness in a range from approximately 40 microns to approximately 1500 microns.

17. A method of manufacturing an electronic device, comprising:
providing a substrate comprising:
a substrate first side comprising a peripheral portion and a central portion surrounded by the peripheral portion;
a substrate second side opposite to the substrate first side;
a substrate lateral side;
a dielectric structure; and
a conductive structure;
providing a first electronic component comprising:
a component first side coupled to the conductive structure at the substrate first side of the substrate in the central portion;
a component second side opposite to the component first side; and
a component lateral side connecting the component first side to the component second side;
providing a stiffener coupled to the substrate first side in the peripheral portion and comprising:
an inner wall;
an outer wall opposite to the inner wall; and
a top side; and
providing an encapsulant covering the inner wall, the outer wall, and the component lateral side, and a portion of the substrate first side, wherein the component second side is exposed from a top side of the encapsulant.

18. The method of claim 17, further comprising:
providing an attachment material;
providing a lid; and
and attaching the lid to the top side of the encapsulant with the attachment material.

19. The method of claim 17, wherein:
providing the encapsulant comprises providing the encapsulant covering the top side of the stiffener; and
providing the encapsulant comprises providing the encapsulant comprising a first thickness over the top side of the stiffener that is greater than approximately 50 microns.

20. The method of claim 17, wherein:
providing the encapsulant comprising providing the top side of the stiffener is exposed from the top side of the encapsulant; and
the top side of the stiffener, the top side of the encapsulant, and the component second side of the first electronic component are substantially coplanar.
